(19) United States
(12) Patent Application Publication
(10) Pub. No.: US 2023/0200171 A1
(43) Pub. Date: Jun. 22, 2023

(54) Organic Light Emitting Diode Display

(71) Applicant: LG Display Co., Ltd., Seoul (KR)

(72) Inventor: Se-Hong Park, Paju-si (KR)

(21) Appl. No.: 17/994,684

(22) Filed: Nov. 28, 2022

(30) Foreign Application Priority Data
Dec. 22, 2021 (KR) 10-2021-0184820

(51) Int. Cl. H10K 59/35; H10K 59/121; H10K 59/80; H10K 59/38; H10K 59/122

(52) U.S. Cl. CPC H10K 59/351; H10K 59/1213; H10K 59/879; H10K 59/38; H10K 59/122

(57) ABSTRACT

An organic light emitting diode display includes: a substrate including red, green, and blue sub-pixels each having a non-emission area and an emission area; a plurality of thin film transistors in the non-emission area; a first overcoat layer having a first refractive index and a plurality of microlenses at a surface of the first overcoat layer; a second overcoat layer on the first overcoat layer and having a second refractive index that is greater than the first refractive index; and a plurality of light emitting diodes on the second overcoat layer, wherein a radius and an aspect ratio of a concave portion of a microlens of the red sub-pixel and a radius and an aspect ratio of a concave portion of a microlens of the green sub-pixel are different from a radius and an aspect ratio of a concave portion of a microlens of the blue sub-pixel.

### CROSS REFERENCE TO RELATED APPLICATION

The present application claims the priority benefit of Republic of Korea Patent Application No. 10-2021-0184820 filed in Republic of Korea on Dec. 22, 2021, which is hereby incorporated by reference in its entirety.

### BACKGROUND

### Field of Technology

The present disclosure relates to an organic light emitting diode display, and particularly, relates to an organic light emitting diode display which improves a light extraction efficiency.

### Discussion of the Related Art

Recently, as society enters a full-fledged information age, interest in information displays that process and display a large amount of information has been increased, and as a demand for using portable information media has been increased, various lightweight and thin flat displays have been developed and been in the spotlight.

Among various flat displays, in an organic light emitting diode display, a significant portion of a light emitted from an organic light emitting layer is lost in the process of passing through various components of the organic light emitting diode display and being emitted to the outside, the light emitted to the outside of the organic light emitting diode display accounts for only about 20% of the light produced in the organic light emitting layer.

Since an amount of light emitted from the organic light emitting layer is increased along with an amount of current applied to the organic light emitting diode display, it is possible to increase a luminance of the organic light emitting diode display by applying more current to the organic light emitting diode display. However, this increases power consumption and also reduces a lifetime of the organic light emitting diode display.

### SUMMARY

Accordingly, the present disclosure is directed to a light emitting diode display that substantially obviates one or more of the problems due to limitations and disadvantages of the related art.

An advantage of the present disclosure is to provide a light emitting diode display which can extract a light trapped inside an element to an outside even when introducing a microlens array to an outside of a substrate or forming a microlens inside the display, and thus can improve a light extraction efficiency and increase a lifetime.

Another advantage of the present disclosure is to provide a light emitting diode display which can prevent an occurrence of a rainbow mura (or rainbow stain) that may reduce visibility and cause eye fatigue.

Another advantage of the present disclosure is to provide a light emitting diode display which can improve a contrast ratio by preventing or at least reducing a decrease in a visibility of a black color due to a high reflectance.

Another advantage of the present disclosure is to provide a light emitting diode display which can realize an image of an excellent color sensitivity.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, an organic light emitting diode display includes: a substrate including a plurality of sub-pixels, the plurality of sub-pixels comprising a red sub-pixel, a green sub-pixel, and a blue sub-pixel that each have a non-emission area and an emission area; a plurality of thin film transistors, each thin film transistor in the non-emission area of a corresponding sub-pixel from the plurality of sub-pixels; a first overcoat layer covering the plurality of thin film transistors, the first overcoat layer having a first refractive index and a plurality of microlenses at a surface of the first overcoat layer; a second overcoat layer on the first overcoat layer, the second overcoat layer having a second refractive index that is greater than the first refractive index of the first overcoat layer and having a substantially flat surface; and a plurality of light emitting diodes on the second overcoat layer, each light emitting diode in the emission area of a corresponding sub-pixel from the plurality of pixels, wherein a radius and an aspect ratio of a concave portion of a microlens of the red sub-pixel and a radius and an aspect ratio of a concave portion of a microlens of the green sub-pixel are different from a radius and an aspect ratio of a concave portion of a microlens of the blue sub-pixel.

In one embodiment, a display device comprises: a substrate including a plurality of sub-pixels each having an emission area and a non-emission area, the plurality of sub-pixels including a first sub-pixel configured to emit light of a first color, a second sub-pixel configured to emit light of a second color, and a third sub-pixel configured to emit light of a third color; a plurality of thin film transistors, each thin film transistor in the non-emission area of a corresponding sub-pixel from the plurality of sub-pixels; a first overcoat layer on the plurality of thin film transistors and including a plurality of microlenses at a surface of the first overcoat layer, the plurality of microlenses including a first microlens in the emission area of the first pixel, a second microlens in the emission area of the second pixel, and a third microlens in the emission area of the third pixel; a second overcoat layer on the first overcoat layer; and a plurality of light emitting diodes on the second overcoat layer, each light emitting diode in the emission area of a corresponding sub-pixel from the plurality of pixels, wherein a radius and an aspect ratio of a concave portion of the first microlens is a same as a radius and an aspect ratio of a concave portion of the second microlens, but the radius and the aspect of the concave portion of the first microlens and the radius and the aspect of a concave portion of the second microlens are different from a radius and an aspect ratio of a concave portion of the third microlens.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view illustrating a plurality of sub-pixels of an organic light emitting display device according to an embodiment of the present disclosure;

FIG. 2 is a cross-sectional view illustrating one sub-pixel of an organic light emitting display device according to an embodiment of the present disclosure;

FIG. 3 is an enlarged photograph of microlenses according to an embodiment of the present disclosure;

FIG. 4 is a simulation result of measuring a reflection visibility caused by a rainbow mura;

FIGS. 5A to 5D are simulation graphs measuring a luminance efficiency increase rate due to a refractive index difference between first and second overcoat layers according to an embodiment of the present disclosure;

FIGS. 6A to 6B are graphs of experimental results of measuring a luminance efficiency increase rate for each color according to a radius of a concave portion of a first overcoat layer according to an embodiment of the present disclosure;

FIGS. 7A to 7D and 8A to 8D are contour diagrams measuring a luminance efficiency increase rate for each color according to refractive indices of first and second overcoat layers according to a radius of a concave portion of a microlens according to an embodiment of the present disclosure;

FIGS. 9A to 9D are graphs of experimental results of measuring a luminance efficiency increase rate according to an aspect ratio of a concave portion of a microlens according to an embodiment of the present disclosure;

FIG. 10 is a view schematically illustrating a refraction angle according to a wavelength for each color according to an embodiment of the present disclosure;

FIG. 11 is a cross-sectional view schematically illustrating sub-pixels according to an embodiment of the present disclosure;

FIG. 12 is a cross-sectional view, taken along a line XI-XI′ of FIG. 1, schematically illustrating sub-pixels according to an embodiment of the present disclosure;

FIG. 13 is a graph of a luminance measured according to a viewing angle according to an embodiment of the present disclosure;

FIG. 14 is a graph showing a relative luminance ratio according to a viewing angle according to an embodiment of the present disclosure;

FIG. 15 is a view schematically illustrating an angle formed by an inclined surface of a first overcoat layer according to an embodiment of the present disclosure;

FIG. 16 is a graph measuring a luminance viewing angle for each color according to an embodiment of the present disclosure; and

FIGS. 17 and 18 are cross-sectional views, taken along a line XVI-XVI′ of FIG. 1, illustrating non-emission areas of sub-pixels according to an embodiment of the present disclosure.

### DETAILED DESCRIPTION

Hereinafter, an embodiment according to the present invention is explained with reference to the drawings.

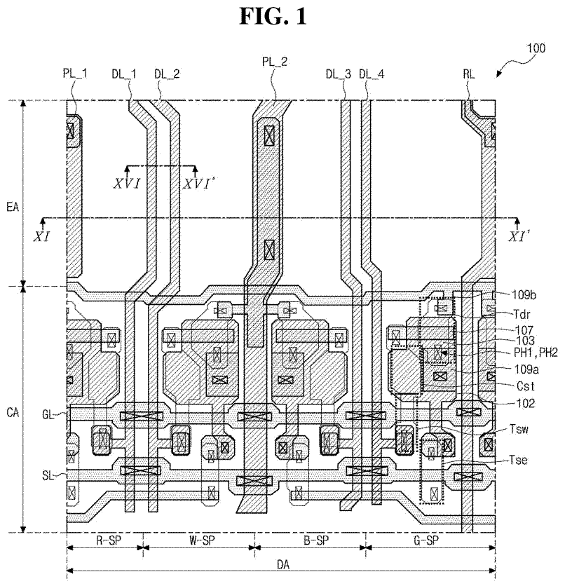

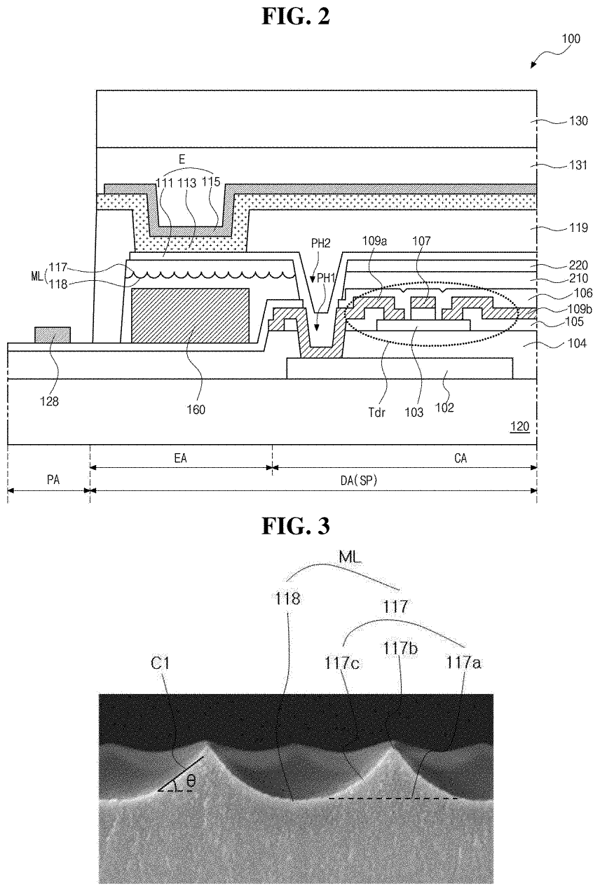

FIG. 1 is a plan view illustrating a plurality of sub-pixels of an organic light emitting display device according to an embodiment of the present disclosure, FIG. 2 is a cross-sectional view illustrating one sub-pixel of an organic light emitting display device according to an embodiment of the present disclosure, and describes a bottom emission type organic light emitting display device as an example.

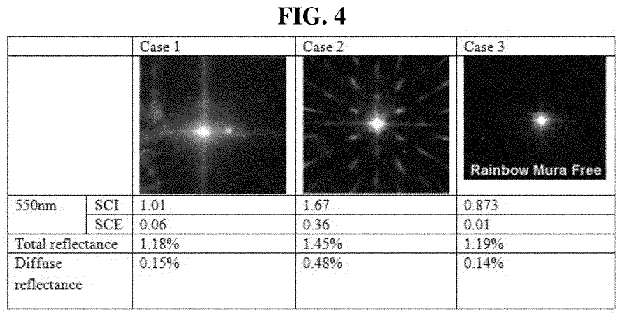

FIG. 3 is an enlarged photograph of microlenses according to an embodiment of the present disclosure.

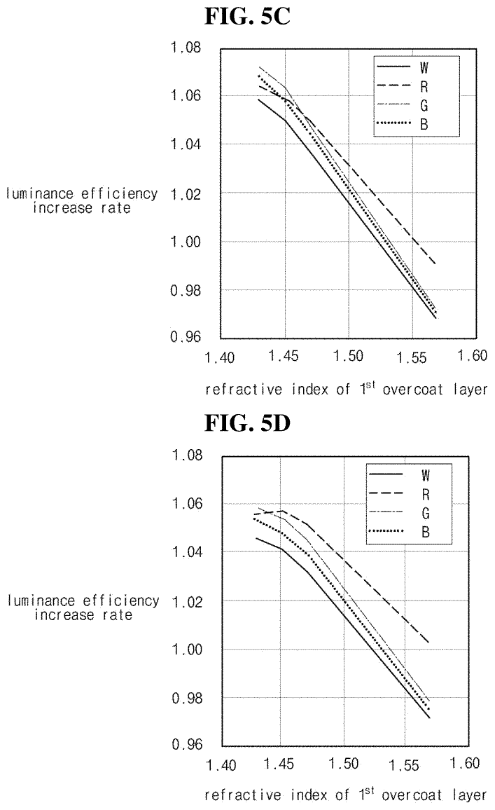

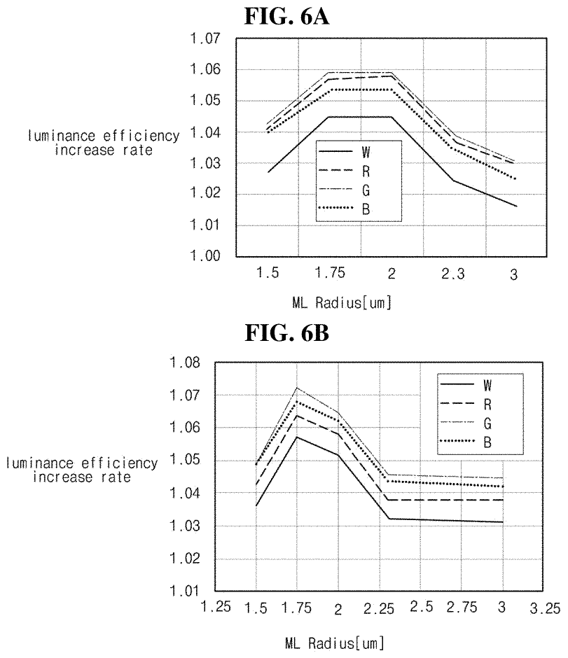

FIGS. 5A to 5D are simulation graphs measuring a luminance efficiency increase rate due to a refractive index difference between first and second overcoat layers according to an embodiment of the present disclosure. FIGS. 6A to 6B are graphs of experimental results of measuring a luminance efficiency increase rate for each color according to a radius of a concave portion of a first overcoat layer according to an embodiment of the present disclosure.

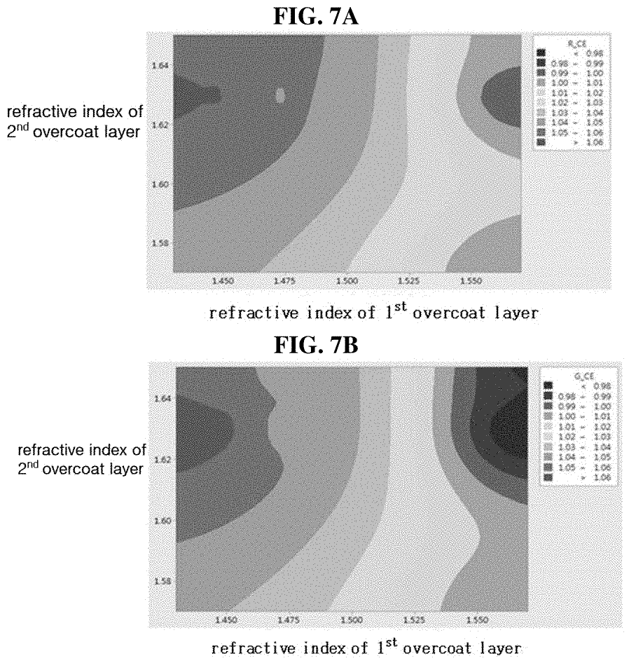

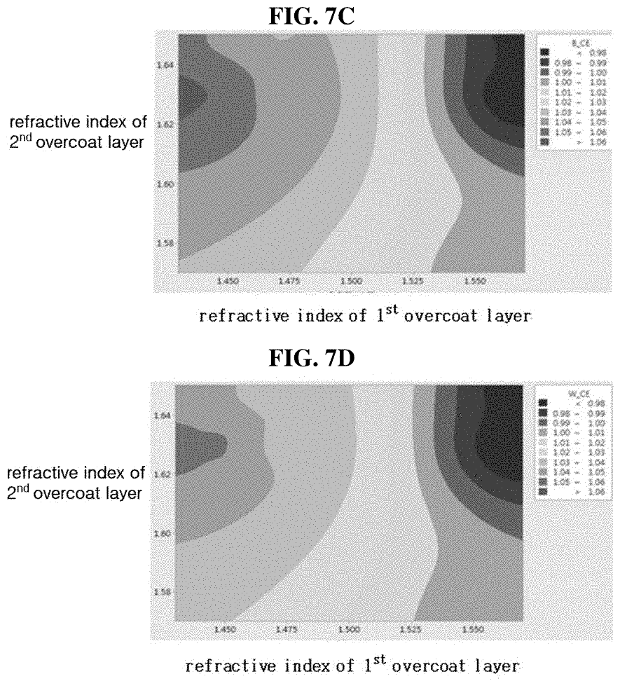

FIGS. 7A to 7D and 8A to 8D are contour diagrams measuring a luminance efficiency increase rate for each color according to refractive indices of first and second overcoat layers according to a radius of a concave portion of a microlens according to an embodiment of the present disclosure. FIGS. 9A to 9D are graphs of experimental results of measuring a luminance efficiency increase rate according to an aspect ratio of a concave portion of a microlens according to an embodiment of the present disclosure.

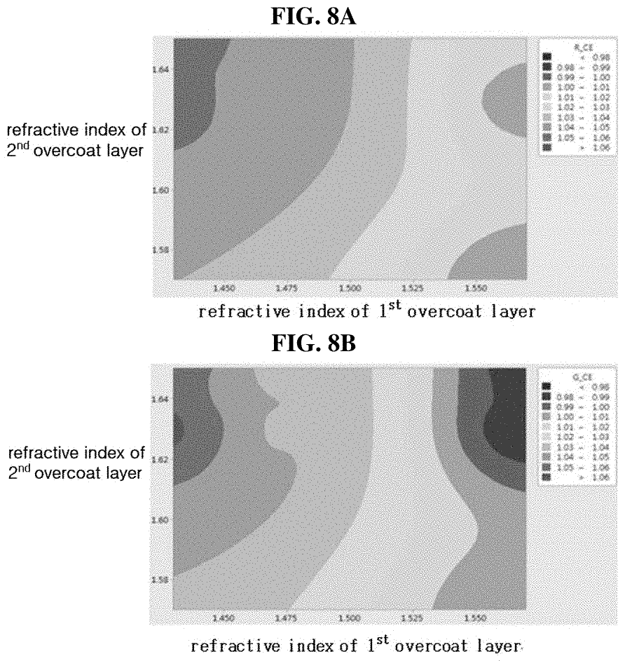

FIG. 10 is a view schematically illustrating a refraction angle according to a wavelength for each color according to an embodiment of the present disclosure.

As shown in FIGS. 1 and 2, the organic light emitting diode display 100 according to the embodiment of the present disclosure may include a substrate 120, a switching thin film transistor Tsw, a driving thin film transistor Tdr, a sensing thin film transistor Tse, a storage capacitor Cst, and a light emitting diode E.

Specifically, the substrate 120 may include a display area DA and a pad area PA disposed around the display area DA. The display area DA may include a plurality of sub-pixels R-SP, W-SP, B-SP, and G-SP, and the plurality of sub-pixels R-SP, W-SP, B-SP, and G-SP may each include an emission area EA and a circuit area CA.

The plurality of sub-pixels R-SP, W-SP, B-SP, and G-SP may emit lights corresponding to red, white, blue, and green, respectively.

The sub-pixel SP of FIG. 2 may be any one of the plurality of sub-pixels R-SP, W-SP, B-SP, and G-SP of FIG. 1.

A light blocking layer 102 may be disposed in the circuit area CA of each of the sub-pixels R-SP, W-SP, B-SP, and G-SP of the display area DA. A pad 128 may be disposed in the pad area PA. At boundaries between the sub-pixels R-SP, W-SP, B-SP, and G-SP, data lines DL_1, DL_2, DL_3, DL_4, power lines PL_1, and PL_2, and a reference line RL may be disposed along a vertical direction.

The pad 128 may be a gate pad connected to a gate line GL, or a data pad connected to the data line DL_1, DL_2, DL_3, or DL_4.

A buffer layer 104 may be disposed on the light blocking layer 102, the pad 128, the data lines DL_1, DL_2, DL_3, and DL_4, the power lines PL_1 and PL_2, and the reference line RL and disposed entirely over the substrate 120. However, the buffer layer 104 may include a first layer of silicon nitride (SiNx) as a lower layer and a second layer of silicon oxide (SiOx) as an upper layer.

A semiconductor layer 103 may be disposed on the buffer layer 104 corresponding to the light blocking layer 102. That is, the semiconductor layer 103 overlaps the light blocking layer 102. The semiconductor layer 103 may include an oxide semiconductor material such as indium-gallium-zinc-oxide (IGZO).

A gate insulating layer 105 may be formed on a central portion and both sides of the semiconductor layer 103 and on the buffer layer 104 at a horizontal boundary portion between the sub-pixels R-SP, W-SP, B-SP, and G-SP.

The gate insulating layer 105 may include semiconductor contact holes exposing both ends of the semiconductor layer 103. The gate insulating layer 105 may include an inorganic insulating material such as silicon oxide (SiOx) or silicon nitride (SiNx).

Both sides of the semiconductor layer 103 exposed through the semiconductor contact holes of the gate insulating layer 105 may be conductorized to operate as a source region and a drain region, and the central portion of the semiconductor layer 103 covered with the gate insulating layer 105 may operate as a channel region.

A gate electrode 107 may be disposed on the gate insulating layer 105 corresponding to the central portion of the semiconductor layer 103, and a source electrode 109a and a drain electrode 109b may be respectively disposed on the gate insulating layer 105 at both sides of the semiconductor layer 103.

In this case, at the horizontal boundaries between the sub-pixels R-SP, W-SP, B-SP, and G-SP, the gate line GL and the sensing line SL may be disposed along a horizontal direction.

The source and drain electrodes 109a and 109b may be in contact with both sides of the semiconductor layer 103 through the semiconductor contact holes, respectively. The source electrode 109a may be in contact with the light blocking layer 102 through a first contact hole PH1.

The gate electrode 107 and the source and drain electrodes 109a and 109b may be formed of a single layer or multiple layers. When the gate electrode 107 and the source and drain electrodes 109a and 109b are formed of a single layer, the gate electrode 107 and the source and drain electrodes 109a and 109b may be one selected from a group consisting of molybdenum (Mo), aluminum (Al), chromium (Cr), gold (Au), titanium (Ti), nickel (Ni), neodymium (Nd), copper (Cu) and an alloy thereof.

In addition, when the gate electrode 107 and the source and drain electrodes 109a and 109b are formed of multiple layers, the gate electrode 107 and the source and drain electrodes 109a and 109b may be formed of multiple layers using one or more of molybdenum (Mo), aluminum (Al), chromium (Cr), gold (Au), titanium (Ti), nickel (Ni), neodymium (Nd), copper (Cu) and an alloy thereof. For example, the gate electrode 107 may have double layers of molybdenum/aluminum-neodymium or molybdenum/aluminum.

In addition, the source and drain electrodes 109a and 109b may have double layers of molybdenum/aluminum-neodymium, or triple layers of titanium/aluminum/titanium, molybdenum/aluminum/molybdenum, or molybdenum/aluminum-neodymium/molybdenum.

The gate electrode 107, the source and drain electrodes 109a and 109b, and the semiconductor layer 103 may constitute the driving thin film transistor Tdr.

Although not shown in the drawings, the switching thin film transistor Tsw and the sensing thin film transistor Tse may have the same structure as the driving thin film transistor Tdr.

A gate electrode of the switching thin film transistor Tsw may be connected to the gate line GL, and a source electrode of the switching thin film transistor Tsw may be connected to the corresponding data line DL_1, DL_2, DL_3, or DL_4, and a drain electrode of the switching thin film transistor Tsw may be connected to the gate electrode 107 of the driving thin film transistor Tdr.

The source electrode 109a of the driving thin film transistor Tdr may be connected to an anode 111 of the light emitting diode E, and the drain electrode 109b of the driving thin film transistor Tdr may be connected to the corresponding power line PL_1 or PL_2.

A gate electrode of the sensing thin film transistor Tse may be connected to the sensing line SL, a source electrode of the sensing thin film transistor Tse may be connected to the anode 111 of the light emitting diode E, and a drain electrode of the sensing thin film transistor Tse may be connected to the reference line RL.

A passivation layer 106 may be disposed on the switching thin film transistor Tsw, the driving thin film transistor Tdr, and the sensing thin film transistor Tse and disposed entirely over the substrate 120.

The passivation layer 106 may include an inorganic insulating material such as silicon oxide (SiOx) or silicon nitride (SiNx).

A color filter layer 160 may be disposed on the passivation layer 106 of the emission area EA of each of the sub-pixels R-SP, W-SP, B-SP, and G-SP of the display area DA.

Regarding the color filter layer 160, red, blue, and green color filter layers may be respectively disposed on the passivation layer 106 of the emission areas EA of the red, green, and blue sub-pixels R-SP, G-SP, and B-SP among the plurality of sub-pixels R-SP, W-SP, B-SP, and G-SP. On the passivation layer 106 of the emission area EA of the white sub-pixel W-SP, a color filter layer may be omitted.

First and second overcoat layers 210 and 220 may be disposed on the color filter layer 160 and the passivation layer 106 entirely over the substrate 120. The first and second overcoat layers 210 and 220 may include an organic insulating material such as photoacrylic.

The first and second overcoat layers 210 and 220 and the passivation layer 106 may include a second contact hole PH2 exposing the source electrode 109a.

The anode 111 may be disposed on the second overcoat layer 220, and the anode 111 may be in contact with the source electrode 109a through the second contact hole PH2.

A bank layer (or bank) 119 may be disposed on the anode 111. The bank layer 119 may include an opening exposing the anode 111 corresponding to the emission area EA of each of the sub-pixels R-SP, W-SP, B-SP, and G-SP of the display area DA.

An organic light emitting layer 113 may be disposed on the anode 111 exposed through the opening of the bank layer 119. A cathode 115 may be disposed on the organic light emitting layer 113 entirely over the substrate 120.

The anode 111, the organic light emitting layer 113, and the cathode 115 may form the light emitting diode E.

Here, the anode 111 may be an electrode providing holes to the organic light emitting layer 113, and may include indium zinc oxide (ITO) having a relatively large work function. The cathode 115 may be an electrode providing electrons to the organic light emitting layer 113, and may include aluminum (Al) or magnesium silver (MgAg) having a relatively small work function.

The organic light emitting layer 113 may include a hole injecting layer, a hole transporting layer, an emitting material layer, an electron transporting layer, and an electron injecting layer.

After placing a protective film 130 in a form of a thin film on the driving thin film transistor Tdr and the light emitting diode E, a face seal 131 made of an organic or inorganic insulating material which is transparent and has an adhesive property may be interposed between the light emitting diode E and the protective film 130 to bond the protective film 130 and the substrate 120 made of an organic or inorganic insulating material, so that the organic light emitting diode display 100 may be encapsulated.

Here, the protective film 130 may be formed by laminating at least two inorganic protective films in order to prevent or at least reduce external oxygen and moisture from penetrating into the organic light emitting diode display 100. In one embodiment, an organic protective film is interposed between the two inorganic protective films to supplement an impact resistance of the inorganic protective films.

In the structure in which the organic protective film and the inorganic protective film are alternately and repeatedly laminated, the inorganic protective films completely enclose the organic protective film because it is necessary to prevent or at least reduce moisture and oxygen from penetrating through a side surface of the organic protective film.

Accordingly, the organic light emitting diode display 100 can prevent or at least reduce moisture and oxygen from penetrating into the organic light emitting diode display 100 from the outside.

As the organic light emitting diode display 100 according to the embodiment of the present disclosure may be a bottom emission type display, a light emitted from the organic light emitting layer 113 passes through the substrate 120 and is transmitted to a user, thereby displaying an image.

Here, in the organic light emitting diode display 100 according to the embodiment of the present disclosure, as shown in FIG. 3, a surface of the first overcoat layer 210 may have a plurality of concave portions 118 and a plurality of convex portions 117 alternately arranged to form microlens ML.

Here, the convex portion 117 may have a structure that defines or surrounds each concave portion 118, and the convex portion 117 may include a bottom portion 117a, a top portion 117b, and a side surface portion 117c.

Here, the side surface portion 117c may be a region including a maximum inclination (Smax) of the convex portion 117, and may be an entire inclined surface forming the top portion 117b.

At this time, an inclination θ formed between a tangent line Cl of the side surface portion 117c and a horizontal plane (i.e., the bottom portion 117a) may be an angle in in a range of 20 to 60 degrees. When the inclination θ is less than 20 degrees, since a light propagation angle by the microlens ML is not significantly different from that of an organic light emitting diode display in which the first overcoat layer 210 is flat, there is little improvement in efficiency.

In addition, when the inclination θ exceeds 60 degrees, a light propagation angle is formed to be larger than a total reflection angle between the substrate 120 and an air layer outside the substrate 120, and an amount of light trapped inside the organic light emitting diode display is greatly increased. Thus, an efficiency is less than that of an organic light emitting diode display in which the first overcoat layer 210 is flat.

As described above, as the inclination θ between the tangent line Cl of the side surface portion 117c and the horizontal plane (i.e., the bottom portion 117a) is defined as an angle in a range of 20 to 60 degrees, the concave portion 118 and the top portion 117b may be defined as regions in which the inclination θ is less than 20 degrees, and the side surface portion 117c may be defined as a region in which the inclination θ is 20 degrees or more.

The convex portion 117 of the first overcoat layer 210 may have the top portion 117b having a pointed structure in order to further increase a light extraction efficiency of the organic light emitting layer 113. The convex portion 117 may have a triangular cross-sectional structure including a vertex corresponding to the top portion 117b, a base corresponding to the bottom portion 117a, and a hypotenuse corresponding to the side surface portion 117c.

A propagation path of a light emitted from the organic light emitting layer 113 is changed toward the substrate 120 through the convex portion 117, so that the organic light emitting diode display 100 according to the embodiment of the present invention can improve a light extraction efficiency.

The second overcoat layer 220 positioned on the first overcoat layer 210 including the microlenses ML may cover the microlenses ML of the first overcoat layer 210 to have a flat surface.

In this case, the second overcoat layer 220 and the first overcoat layer 210 may have different refractive indices, and the refractive index of the second overcoat layer 220 is greater than that of the first overcoat layer 210 in one embodiment.

Here, the anode 111, the organic light emitting layer 113, and the cathode 115 sequentially positioned on the second overcoat layer 220 may all be formed to be flat along the flat surface of the second overcoat layer 220.

Accordingly, as the organic light emitting layer 113 is formed to have a uniform thickness for each of the sub-pixels R-SP, W-SP, G-SP, and B-SP, the emission characteristic can be also uniform for each of the sub-pixels R-SP, W-SP, G-SP, and B-SP. Accordingly, an efficiency of the organic light emitting layer 113 for each region within each of the sub-pixels R-SP, W-SP, G-SP, and B-SP can be improved, and a lifespan can also be improved.

Here, in the organic light emitting diode display 100 according to the embodiment of the present disclosure, the first and second overcoat layers 210 and 220 having different refractive indices may be stacked on each other, and the first overcoat layer 210 may include the microlens ML, and the second overcoat layer 220 may cover the micro lens ML to be planarized, thereby improving a light extraction efficiency and preventing an occurrence of a rainbow mura.

Here, the rainbow mura may be generated through a reflection visibility due to an interference of visible light as a light emitted from each organic light emitting layer 113 is refracted through a curved surface and a path of the light is changed. In the organic light emitting diode display 100 according to the present disclosure, as the organic light emitting layer 113 is positioned on the second overcoat layer 220 having a flat surface, the rainbow spot do not occur.

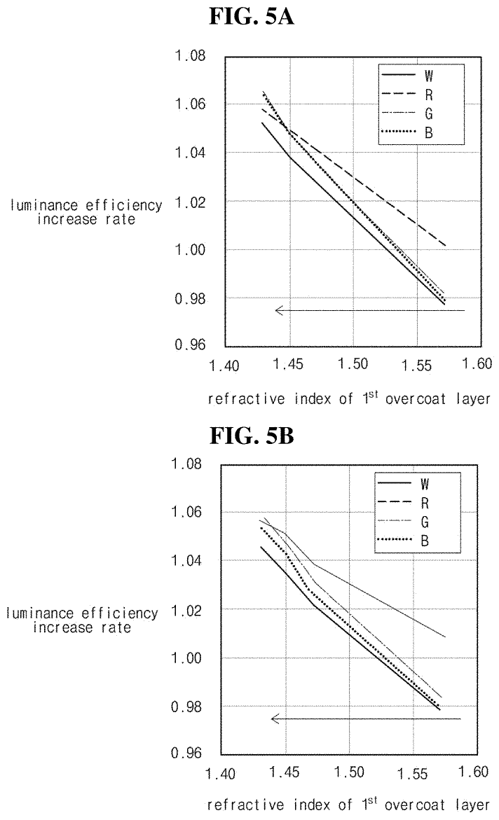

FIG. 4 shows a simulation result of measuring a reflection visibility caused by a rainbow mura. Case 1 shows a configuration of a general organic light emitting diode display, and case 2 shows a configuration of an organic light emitting diode display in which a rainbow stain is generated.

Case 3 show a configuration as in the embodiment of the present disclosure in which the first and second overcoat layers 210 and 220 having different refractive indices are stacked on each other, the first overcoat layer 210 includes the microlens ML, and the second overcoat layer 220 cover the micro lenses ML to be planarized.

In FIG. 4, the total reflectance means that a specular reflectance and a diffuse reflectance are combined. The specular reflection (or regular reflection) means a reflection of a light in which an incident angle is equal to a reflected angle, and a ratio of a light scattered in many directions without causing the specular reflection is called a diffuse reflectance. A color measurement method excluding a specular reflected light is called a SCE (Specular Component Excluded) method. If a specular reflected light is included to complete an integrating sphere in color measurement, it is called SCI (Specular Component Included) method.

When measuring using the SCE method, a specular reflected light is completely excluded and only a diffused reflected light is measured. This opens a way for correlation when an observer sees a color of an object, so that a color can be evaluated.

When the SCI method is used, a specular reflectance and a diffuse reflectance are included in a measurement process. In this method, a color evaluation can be performed without being affected by a state of a surface.

Referring to FIG. 4, it is seen that both SCI and SCE of case 2 are higher than those of case 1 and case 3. Therefore, it is seen that a total reflectance of case 2 is also higher than those of case 1 and case 3.

It is seen that a rainbow mura appear clearly in case 2. In contrast, it is seen that a rainbow stain is hardly recognized in case 1 and case 3.

In particular, it is seen that in case 3 of the present disclosure, a separate polarizing plate for suppressing an external light reflection is not included, but a rainbow mura are hardly recognized like case 1.

This means that in the organic light emitting diode display 100 according to the embodiment of the present disclosure, a reflective visibility is reduced and thus a rainbow mura are not generated.

In addition, by reducing the reflection visibility, it is possible to prevent a high reflectance from occurring, and accordingly, a deterioration of a visibility of a black color can be prevented, thereby improving a contrast ratio.

Here, the first overcoat layer 210 may have a refractive index in a range of 1.43 to 1.57, and the second overcoat layer 220 may have a refractive index in a range of 1.57 to 1.8. A light extraction efficiency varies depending on a refractive index difference between the first overcoat layer 210 and the second overcoat layer 220.

By setting a refractive index difference between the first overcoat layer 210 and the second overcoat layer 220 to be 0.2, a light extraction efficiency can be further improved.

FIGS. 5A to 5D are simulation results of measuring an efficiency increase rate due to a refractive index difference between first and second overcoat layers 210 and 220. In the graph, the horizontal axis represents the refractive index of the first overcoat layer 210, and the vertical axis represents a luminance efficiency increase rate.

FIGS. 5A and 5B relate to case I, FIG. 5A shows a luminance efficiency increase rate for each color measured according to the refractive index of the first overcoat layer 210 when the refractive index of the second overcoat layer is 1.63, and FIG. 5B shows a luminance efficiency increase rate for each color measured according to the refractive index of the first overcoat layer 210 when the refractive index of the second overcoat layer is 1.65. FIGS. 5C and 5D relate to case II, FIG. 5C shows a luminance efficiency increase rate for each color measured according to the refractive index of the first overcoat layer 210 when the refractive index of the second overcoat layer is 1.63, and FIG. 5D shows a luminance efficiency increase rate for each color measured according to the refractive index of the first overcoat layer 210 when the refractive index of the second overcoat layer is 1.65.

Case I and case II are described with reference to FIGS. 5A to 5D. It is seen that when the refractive index of the second overcoat layer 220 is the same in both case I and case II, the luminance efficiency increase rate increases as the refractive index of the first overcoat layer 210 decreases. It is seen that when the refractive index of the first overcoat layer 210 is the same, the luminance efficiency increase rate is greater in the case that the refractive index of the second overcoat layer 220 is 1.63.

This means that when the first overcoat layer 210 has the refractive index of 1.43 and the second overcoat layer 220 has the refractive index of 1.65, the luminance efficiency increase rate is the greatest. Accordingly, it is seen that the light extraction efficiency can be further improved by setting the refractive index difference between the first overcoat layer 210 and the second overcoat layer 220 to be 0.2.

In one embodiment, the first overcoat layer 210 is formed similarly to the passivation layer 106 positioned below the first overcoat layer 210 so as to match the refractive indices thereof. That is, it is desirable to prevent a total reflection due to a refractive index difference between the first overcoat layer 210 and the passivation layer 106.

In more detail, the passivation layer 106 and the first overcoat layer 210 may have a refractive index in a range of 1.43 to 1.57, and the second overcoat layer 220 may have a refractive index in a range of 1.57 to 1.8 in one embodiment. In this case, the first overcoat layer 210 and the second overcoat layer 220 may have a refractive index difference of 0.2.

Accordingly, when a light is emitted from the organic light emitting layer 113 positioned on the flat surface of the second overcoat layer 220, the light passes through the second overcoat layer 220 and is incident on the first overcoat layer 210. In this case, the organic light emitting diode display 100 according to the embodiment of the present disclosure includes the microlenses ML at the surface of the first overcoat layer 210, so that a propagation path of a light that is not extracted to an outside due to repeated total reflection inside the first and second overcoat layers 210 and 220 may be changed toward the substrate 120.

At this time, the light proceeding from the second overcoat layer 220 to the first overcoat layer 210 may be focused.

In addition, in a process in which the light passing through the first overcoat layer 210 is incident on the passivation layer 106 having a refractive index similar to that of the first overcoat layer 210, a total reflection occurring due to a refractive index difference between the first overcoat layer 210 and the passivation layer 106 is prevented or at least reduced. Thus, all of the light passing through the first overcoat layer 210 may be incident on the passivation layer 106.

Therefore, it is seen that a light extraction efficiency can be improved.

In addition, in the organic light emitting diode display 100 according to the embodiment of the present disclosure, depending on the refractive index difference between the first and second overcoat layers 210 and 220, a luminance efficiency increase rate according to a radius (r) of the concave portion 118 of the microlens ML of the first overcoat layer 210 may also vary.

FIGS. 6A to 6B show experimental results of measuring a luminance efficiency increase rate for each color according to the radius (r) of the concave portion 118 of the first overcoat layer 210. In the graphs, the horizontal axis represents the radius (r) of the concave portion 118 of the first overcoat layer 210, and the vertical axis represents the luminance efficiency increase rate.

At this time, the microlens ML of FIGS. 6A and 6B is designed so that the concave portions 118 have the same aspect ratio (A/R), which is 1.

Here, a diameter (D) of the concave portion 118 means a length between centers of the two convex portions 117, and a height (H) of the concave portion 118 means a length from an apex of the convex portion 117 to the bottom of the concave portion 118. The aspect ratio (A/R) means a value obtained by dividing the height (H) of the concave portion 118 by the radius (r) of the concave portion 118.

FIG. 6A shows that the refractive index of the first overcoat layer 210 is 1.43, the refractive index of the second overcoat layer 220 is 1.65, and thus the refractive index difference between the first and second overcoat layers 210 and 220 is 0.22, and when the radius (r) of the concave portion 118 of the microlens ML is 1.75 μm and 2.0 μm, the luminance efficiency increase rate for each color is high. When the radius (r) of the concave portion 118 is 1.75 μm and 2.0 μm, the luminance efficiency increase rate of a white light is 1.042(%).

At this time, as shown in FIG. 6B, the refractive index of the first overcoat layer 210 is 1.43, the refractive index of the second overcoat layer 220 is 1.63, and thus the refractive index difference between the first and second overcoat layers 210 and 220 is 0.2, and at this case, when the radius (r) of the concave portion 118 is 1.75 μm, the luminance efficiency increase rate of a white light is 1.059. As such, the luminance efficiency increase rate is further improved, compared to the case where the refractive index difference between the first and second overcoat layers 210 and 220 is 0.22.

This means that even when the radius (r) of the concave portion 118 is 2.0 μm, the case where the refractive index difference between the first and second overcoat layers 210 and 220 is 0.2 is further improved in luminance efficiency increase rate, compared to the case where the refractive index difference is 0.22.

Therefore, it is seen from the experimental results that by setting the refractive index difference between the first overcoat layer 210 and the second overcoat layer 220 to be 0.2, the light extraction efficiency can be further improved.

FIGS. 7A to 7D are contour diagrams measuring a luminance efficiency increase rate for each color according to the refractive indices of first and second overcoat layers 210 and 220 when the radius (r) of the concave portion 118 of the microlens ML is 1.75 μm. FIGS. 8A to 8D are contour diagrams measuring a luminance efficiency increase rate for each color according to the refractive indices of first and second overcoat layers 210 and 220 when the radius (r) of the concave portion 118 of the microlens ML is 2.0 μm.

In the contour diagrams, the horizontal axis represents the refractive index of the first overcoat layer 210, and the vertical axis represents the refractive index of the second overcoat layer 220.

At this time, the concave portions 118 of the micro lenses ML of FIGS. 7A to 7D and 8A to 8D are all designed to have the same aspect ratio (A/R), and in this case, the aspect ratios (A/R) of the concave portions 118 of the micro lenses ML is 1.

Referring to the contour diagrams of FIGS. 7A to 7D, it is seen that when the refractive index of the first overcoat layer 210 is 1.450 or less and the refractive index of the second overcoat layer 220 is 1.62 or more, the luminance efficiency increase rate is greatest.

In addition, even referring to the contour diagrams of FIGS. 8A to 8D, it is seen that when the refractive index of the first overcoat layer 210 is 1.450 or less and the refractive index of the second overcoat layer 220 is 1.62 or more, the luminance efficiency increase rate is greatest.

Accordingly, it is seen that when the first overcoat layer 210 has a refractive index of 1.43, the second overcoat layer 220 has a refractive index of 1.63, and thus the refractive index difference between the first and second overcoat layers 210 and 220 is 0.2, the light extraction efficiency can be further improved.

In particular, comparing FIGS. 7D and 8D, it is seen that a white light has a maximum luminance efficiency increase rate when the radius (r) of the concave portion 118 of the microlens ML having the aspect ratio A/R of 1 is 1.75 μm compared to when the radius (r) of the concave portion 118 is 2.0 μm.

This means that when the aspect ratio (A/R) of the concave portion 118 of the microlens (ML) is 1, the radius (r) being 1.75 μm can further improve the light extraction efficiency of the white light.

Here, the luminance efficiency increase rate may also vary depending on the aspect ratio (A/R) of the concave portion 118 of the microlens ML of the first overcoat layer 210. This is described in more detail with reference to FIGS. 9A to 9D.

FIGS. 9A to 9D are experimental results of measuring the luminance efficiency increase rate according to the aspect ratio (A/R) of the concave portion 118 of the microlens ML. FIGS. 9A and 9B show the luminance efficiency increase rate of each color measured by varying the refractive index difference between the first and second overcoat layers 210 and 220 when the radius (r) of the concave portion 118 of the microlens ML is the same. FIGS. 9C and 9D show the luminance efficiency increase rate for each color measured by varying the radius (r) of the concave portion 118 of the microlens ML when the refractive index difference between the first and second overcoat layers 210 and 220 is equally designed as 0.2.

That is, in FIGS. 9A and 9B, the radius r of the concave portion 118 of the microlens ML is 2.0 μm; in FIG. 9A, the refractive index difference Δn between the first overcoat layer 210 and the second overcoat layer 220 is designed to be 0.16; and in FIG. 9B, the refractive index difference Δn between the first overcoat layer 210 and the second overcoat layer 220 is designed to be 0.18.

In FIGS. 9C and 9D, the refractive index difference Δn of the first and second overcoat layers 210 and 220 is 0.2. In FIG. 9C, the radius (r) of the concave portion 118 of the microlens ML is designed to be 2.0 μm. In FIG. 9D, the radius (r) of the concave portion 118 of the microlens ML is designed to be 1.75 μm.

Referring to FIGS. 9A and 9D, it is seen that when the aspect ratio (A/R) of the concave portion 118 of the microlens ML becomes smaller than 1, a luminance efficiency increase rate of a red light is greater than luminance efficiency increase rates of green light and blue light, and the luminance efficiency increase rate of green light is greater than the luminance efficiency increase rate of blue light (i.e., R>G>B).

On the other hand, it is seen that when the aspect ratio (A/R) of the concave portion 118 of the microlens ML becomes larger than 1, the luminance efficiency increase rate of the blue light is the greatest, the luminance efficiency increase rate of the green light is the next greatest, and the luminance efficiency increase rate of the red light is the lowest (i.e., B>G>R).

In addition, referring to FIG. 9D, it is seen that when the radius (r) of the concave portion 118 of the microlens ML is 1.75 μm, the luminance efficiency increase rate is greatest in the case that the aspect ratio (A/R) of the concave portion 118 is 1. Furthermore, referring to 8A to 8C, it is seen that when the radius (r) of the concave portion 118 is 2.0 μm, the luminance efficiency increase rates of the red light and green light are greatest in the case that the aspect ratio (A/R) of the concave portion 118 is 1, and the luminance efficiency increase rate of the blue light is greatest in the case that the aspect ratio (A/R) of the concave portion 118 is 1.25.

Through these experimental results, regarding red light and green light, when the radius (r) of the concave portion 118 of the microlens (ML) is 1.75 μm, the aspect ratio (A/R) is set to 1, so that the maximum luminance efficiency increase rate can be obtained. Regarding blue light, when the radius (r) of the concave portion 118 of the microlens ML is 2.0 μm, the aspect ratio (A/R) is set to 1.25, so that the maximum luminance efficiency increase rate can be obtained.

In addition, referring to FIG. 9D, regarding the white light, when the radius (r) of the concave portion 118 of the microlens ML is 1.75 μm, the aspect ratio (A/R) is set to 1, so that the maximum luminance efficiency increase rate can be obtained.

In addition, referring to FIGS. 9C and 9D, when the refractive index difference of first and second overcoat layers 210 and 220 is the same, as the aspect ratio (A/R) of the concave portion 118 of the microlens ML increases, the luminance efficiency increase rate of blue light is greater than those of the red light and the green light. This is because refraction angles of red light and green light are less than that of blue light, as shown in FIG. 10, and thus amounts of the red light and the green light emitted outside the substrate 120 is less than that of the blue light.

Accordingly, in the organic light emitting diode display 100 according to the embodiment of the present disclosure, the radius (r) of the concave portion 118 of the microlens ML in the first overcoat layer 210 of the red and green sub-pixels R-SP and G-SP is designed to be 1.75 μm, and the aspect ratio (A/R) is set to 1. The radius (r) of the concave portion 118 of the microlens (ML) in the first overcoat layer 210 of the blue sub-pixel B-SP is designed to be 2.0 μm, and the aspect ratio (A/R) is set to 1.25.

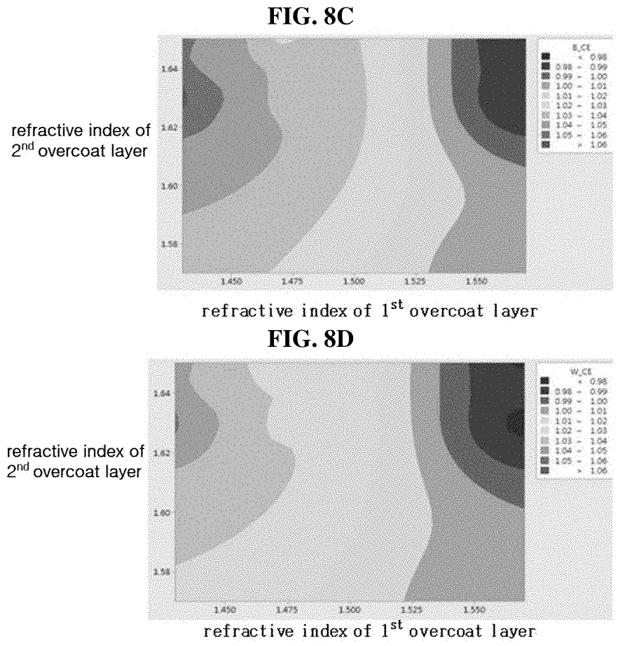

FIG. 11 is a cross-sectional view schematically illustrating sub-pixels according to an embodiment of the present invention.

As shown in FIG. 11, in the organic light emitting diode display (100 of FIG. 2) according to the embodiment of the present disclosure, a plurality of sub-pixels R-SP, W-SP, G-SP, and B-SP may be defined on the substrate 120. A gate insulating layer 105 and a passivation layer 106 may be positioned on the substrate 120, a red color filter layer 160r may be disposed on the passivation layer 106 of the red sub-pixel R-SP, and a green color filter layer 160g may be disposed on the passivation layer 106 of the green sub-pixel G-SP.

In addition, a blue color filter layer 160b may be disposed on the passivation layer 106 of the blue sub-pixel B-SP. A color filter layer may be omitted on the passivation layer 106 in the white sub-pixel W-SP.

A first overcoat layer 210 may be disposed on the color filter layers 160r, 160g, and 160b and the passivation layer 106 entirely over the substrate 120. The first overcoat layer 210 may have a plurality of concave portions 118 and a plurality of convex portions 117 alternately arranged to form microlenses ML.

As described above, in the organic light emitting diode display (100 of FIG. 2) according to the embodiment of the present disclosure, by forming the microlenses ML at the first overcoat layer 210, a propagation path of a light that is not extracted to an outside due to repeated total reflection inside the organic light emitting diode display (100 of FIG. 2) is changed toward the substrate 120, so that a light extraction efficiency can be improved.

A second overcoat layer 220 may be positioned on the first overcoat layer 210 that includes the microlens ML. The second overcoat layer 220 may cover the microlens ML of the first overcoat layer 210 to have a flat surface.

An anode 111, an organic light emitting layer 113, and a cathode 115 sequentially positioned on the second overcoat layer 220 may be all formed to be flat along the flat surface of the second overcoat layer 220.

Accordingly, as the organic light emitting layer 113 is formed to have a uniform thickness for each of the sub-pixels R-SP, W-SP, G-SP, and B-SP, an emission characteristic can be uniform for each of the sub-pixels R-SP, W-SP, G-SP, and B-SP. Accordingly, an efficiency of the organic light emitting layer 113 for each region within each of the sub-pixels R-SP, W-SP, G-SP, and B-SP can be improved, and a lifespan can also be improved.

In this case, the concave portions 118 of the microlenses ML positioned corresponding to the red sub-pixel R-SP, the white sub-pixel W-SP, and the green sub-pixel G-SP may have a radius (r) of 1.75 μm and, in this case, may have an aspect ratio (A/R) of 1, so that the red, white, and green sub-pixels R-SP, W-SP, and G-SP may have a maximum luminance efficiency increase rate.

In addition, the microlens ML positioned to correspond to the blue sub-pixel B-SP may have a radius (r) of the concave portion 118 of 2.0 μm, and an aspect ratio A/R of 1.25, so that the blue sub-pixel B-SP may have a maximum luminance efficiency increase rate.

Accordingly, the organic light emitting diode display (100 of FIG. 2) according to the embodiment of the present disclosure can further improve a light extraction efficiency.

A following Table 2 shows experimental results of measuring a WCT, a color temperature, and a basic afterimage according to a radius (r) and an aspect ratio (A/R) of the concave portion 118 of various microlenses ML.

TABLE 2

| | | case A | case B | case C | case D | case E | case F |
|---|---|---|---|---|---|---|---|
| Radius (μm) | | | R/W/G/ | R/W/G/ | R/W/G/ | R/W/G 2.0, | R/W/G 1.75, |
| | | | B 2.0 | B 2.0 | B 2.0 | B 1.75 | B 2.0 |
| Aspect ratio | | | R/W/G/ | R/W/G/ | R/W/G 1, | R/W/G/ | R/W/G 1, |
| (A/R) | | | B 1 | B 1.25 | B 1.25 | B 1 | B 1.25 |
| WCT | | 177 | 184 | 186 | 186 | 184 | 184 |
| R efficiency | | 7.49 | 7.93 | 7.86 | 7.93 | 7.93 | 7.97 |
| (cd/A) | | | | | | | |
| G efficiency | | 23.76 | 25.31 | 25.15 | 25.31 | 25.31 | 25.46 |
| (cd/A) | | | | | | | |
| B efficiency | | 3.97 | 4.22 | 4.26 | 4.26 | 4.24 | 4.26 |
| (cd/A) | | | | | | | |
| W efficiency | | 70.37 | 74.06 | 73.56 | 73.56 | 74.46 | 74.46 |
| (cd/A) | | | | | | | |
| Color | | 8566 K | 8799 K | 9055 K | 9055 K | 8788 K | 8788 K |
| temperature_Wsub | | | | | | | |
| Basic | W | 11800 | 12800 | 12700 | 12800 | 13000 | 13000 |
| after | R | 22900 | 24800 | 24100 | 24700 | 24800 | 25000 |
| image | G | 21000 | 23500 | 23200 | 23400 | 23500 | 23800 |
| | B | 22700 | 25200 | 26300 | 26300 | 25300 | 26300 |

In Table 2, case A represents a general organic light emitting diode display, and case B, case C, case D, case E, and case F represents organic light emitting diode displays in which microlenses (ML) are provided at a surface of the first overcoat layer 210 and the overcoat layer 220 covers the first overcoat layer 210 to form a flat surface.

Here, in case B, the concave portions 118 of the microlenses ML corresponding to the red, white, blue, and green sub-pixels R-SP, W-SP, G-SP, and B-SP are designed to have the radius (r) of 2.0 μm and the aspect ratio (A/R) of 1.0. In case C, the concave portions 118 of the microlenses ML corresponding to the red, white, blue, and green sub-pixels R-SP, W-SP, G-SP, and B-SP are designed to have the radius (r) of 2.0 μm, and the aspect ratio (A/R) of 1.25.

In case D, the concave portions 118 of the microlenses ML corresponding to the red, white, blue, and green sub-pixels R-SP, W-SP, G-SP, and B-SP are designed to have the radius (r) of 2.0 μm, the concave portions 118 of the microlenses ML corresponding to the red, green, and white sub-pixels R-SP, G-SP, and W-SP are designed to have the aspect ratio (A/R) of 1.0, and the concave portion 118 of the microlens ML corresponding to the blue sub-pixel B-SP is designed to have the aspect ratio (A/R) of 1.25.

In case E, the concave portions 118 of the microlenses ML corresponding to the red, green, and white sub-pixels R-SP, G-SP, and W-SP are designed to have the radius (r) of 2.0 μm, the concave portion 118 of the microlens ML corresponding to the blue sub-pixel B-SP is designed to have the radius (r) of 1.75 μm, and the concave portions 118 of the microlenses ML corresponding to the red, white, blue, and green sub-pixels R-SP, W-SP, B-SP and G-SP are designed to have the aspect ratio (A/R) of 1.0.

As in the embodiment of the present disclosure, in case F, the concave portions 118 of the microlenses ML corresponding to the red, green, and white sub-pixels R-SP, G-SP, and W-SP are designed to have the radius (r) of 1.75 μm, the concave portion 118 of the microlens ML corresponding to the blue sub-pixel B-SP is designed to have the radius (r) of 2.0 μm, the concave portions 118 of the microlenses ML corresponding to the red, white, and green sub-pixels R-SP, W-SP, and G-SP are designed to have the aspect ratio (A/R) of 1.0, and the concave portion 118 of the microlens ML corresponding to the blue sub-pixels B-SP is designed to have the aspect ratio (A/R) of 1.25.

Prior to explanations, the white color tracking (WCT) represents a full white gray level. The color temperature expresses a chromaticity of a light source or reference white as a temperature of a closest region on a radiation curve instead of a coordinate on a two-dimensional chromaticity chart, and may be also called a correlated color temperature (CCT). The color temperature is used as a numerical value indicating a degree to which a white color is close to a certain color.

The higher the color temperature, the higher a quality of color expression. In particular, in order for a display device that displays an image using a light emitting diode E to express a high-quality color, it is desirable that the color temperature of a white is high. Accordingly, recently, a very high color temperature of at least 7000K or more is required for a white emitted from a display device.

Referring to Table 2, it is seen that case B, case C, case D, case E, and case F all have higher WCT and color temperature than case A, and in particular, the color temperature is 7000K or higher.

It is seen that among case A, case B, case C, case D, case E, and case F, case E and case F have the highest W efficiency, and case F has the highest R, G, and B efficiencies.

In particular, it is seen that case F has the basic afterimage that is higher than case A, case B, case C, case D, and case E. The basic afterimage is a lifespan of the organic light emitting layer 113, it is seen that case F has the afterimage improved by about 10% or more compared to case A.

Accordingly, in the organic light emitting diode display (100 of FIG. 2) according to the embodiment of the present disclosure, the concave portions 118 of the microlenses ML positioned to correspond to the red, white, and green sub-pixels R-SP, G-SP, and W-SP have the radius (r) of 1.75 μm and the aspect ratio (A/R) of 1, so that the red, white and green sub-pixels R-SP, W-SP, and G-SP have the maximum luminance efficiency increase rate.

In addition, the concave portion 118 of the microlens ML positioned to correspond to the blue sub-pixel B-SP has the radius (r) of 2.0 μm and the aspect ratio (A/R) of 1.25, so that the blue sub-pixel B-SP has the maximum luminance efficiency increase rate.

Accordingly, the organic light emitting diode display (100 of FIG. 2) according to the embodiment of the present disclosure can further improve a light extraction efficiency.

In particular, since the organic light emitting diode display (100 of FIG. 2) according to the embodiment of the present disclosure can also improve a lifespan, it can reduce a power consumption, and finally, an efficiency of the organic light emitting diode display (100 of FIG. 2) can be also improved.

As described above, in the organic light emitting diode display (100 of FIG. 2) according to the embodiment of the present disclosure, the first and second overcoat layers 210 and 220 having different refractive indices are stacked on each other, the first overcoat layer 210 includes the microlens ML, and the second overcoat layer 220 covers the micro lenses ML to be planarized, thereby improving a light extraction efficiency and preventing or at least reducing a rainbow mura.

In addition, by preventing or at least reducing an occurrence of a high reflectance, it is possible to prevent or at least reduce a deterioration of a visibility of a black color, so that a contrast ratio is improved.

In addition, by making the first and second overcoat layers 210 and 220 have a refractive index difference of 0.2, a light extraction efficiency can be further improved, and each of the sub-pixels R-SP, W-SP, G-SP, and B-SP can have a uniform emission characteristic, thereby improving an efficiency of the organic light emitting layer 113 and also increasing a lifespan of the organic light emitting layer 113.

In particular, the radius (r) and aspect ratio (A/R) of the concave portion 118 of the microlens ML for each of the sub-pixels R-SP, W-SP, G-SP, and B-SP are designed to suit each color characteristic. Accordingly, it is possible to have the maximum luminance efficiency increase rate for each of the sub-pixels R-SP, W-SP, G-SP, and B-SP, thereby further improving the light extraction efficiency.

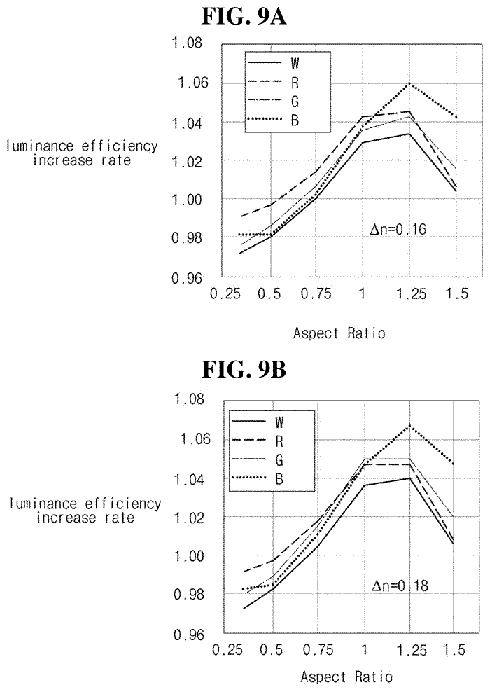

FIG. 12 is a cross-sectional view schematically illustrating sub-pixels according to an embodiment of the present disclosure, and is a cross-sectional view taken along a line XI-XI′ of FIG. 1.

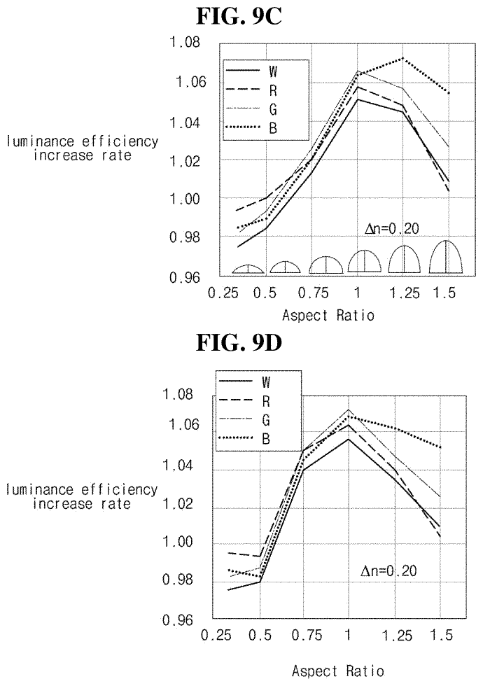

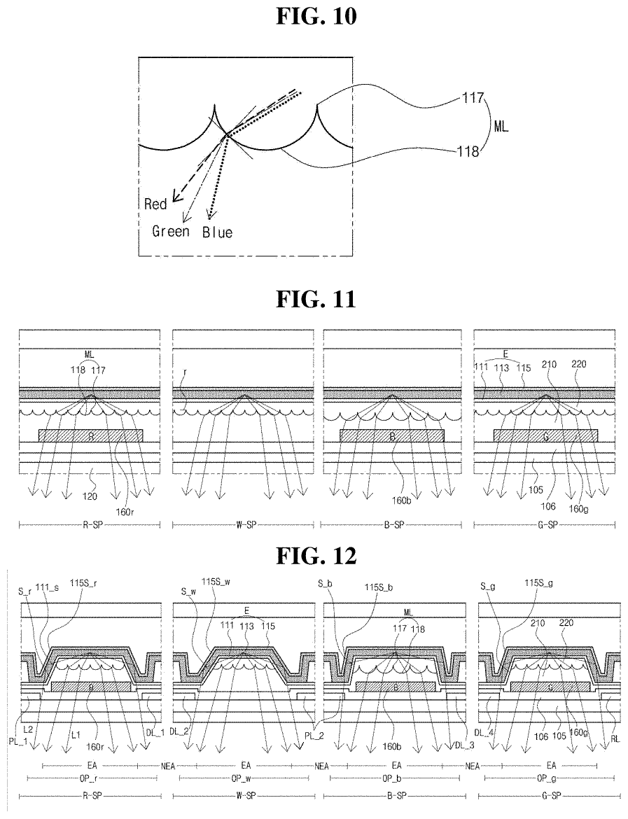

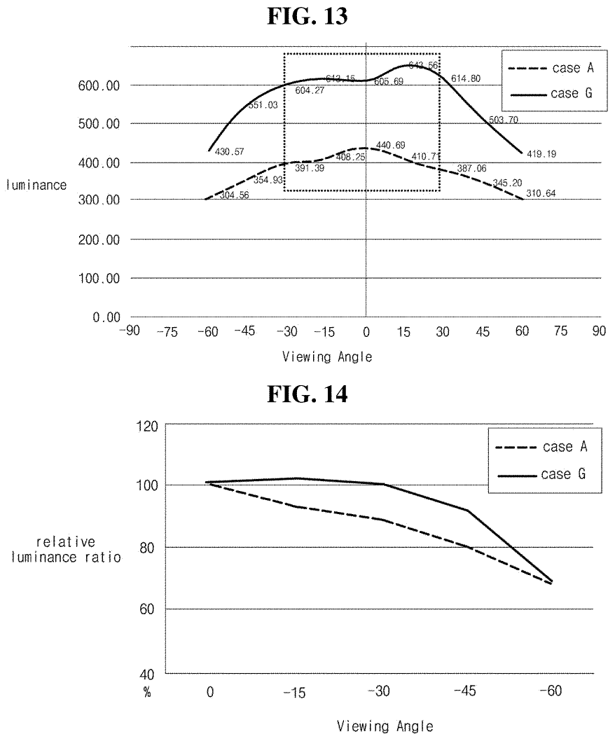

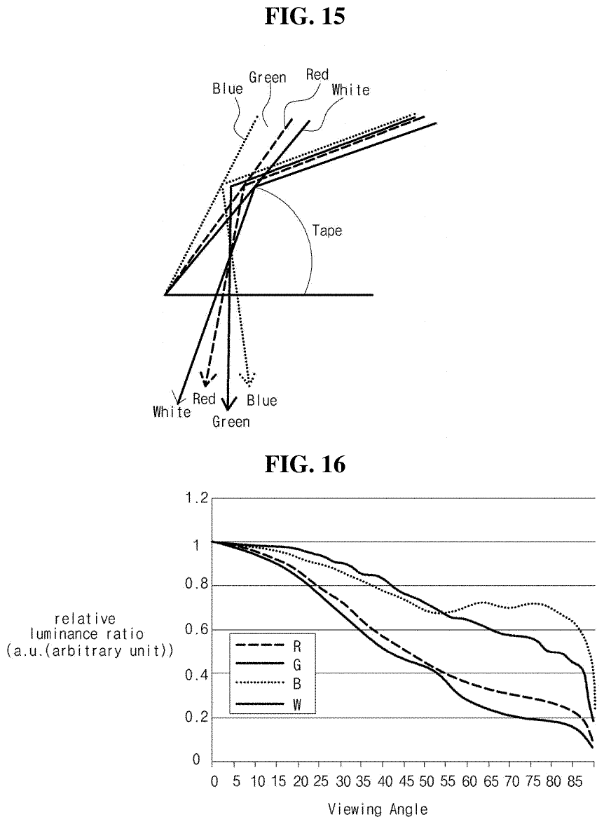

FIG. 13 is a graph of a luminance measured according to a viewing angle according to an embodiment of the present disclosure. FIG. 14 is a graph showing a relative luminance ratio according to a viewing angle according to an embodiment of the present invention. FIG. 15 is a view schematically illustrating an angle formed by an inclined surface of a first overcoat layer according to an embodiment of the present disclosure. FIG. 16 is a graph measuring a luminance viewing angle for each color according to an embodiment of the present disclosure.

As shown in FIG. 12, in the organic light emitting diode display (100 of FIG. 2) according to the embodiment of the present disclosure, a plurality of sub-pixels R-SP, W-SP, G-SP, and B-SP may be defined on a substrate 120. A gate insulating layer 105 may be positioned on the substrate 120. Data lines DL_1, DL_2, DL_3, and DL_4, power lines PL_1 and PL2, and a reference line RL are disposed along a vertical direction at boundaries between the sub-pixels R-SP, W-SP, G-SP, and B-SP on the gate insulating layer 105, and light extraction areas OP_r, OP_w, OP_b, and OP_g may be defined in the respective sub-pixels R-SP, W-SP, B-SP, and G-SP.

That is, the red sub-pixel R-SP may be disposed between the first power line PL_1 and the first data line DL_1, and a red light extraction area OP_r may be defined between the first power line PL_1 and the first data line DL_1. The white sub-pixel W-SP may be disposed between the second data line DL_2 and the second power line PL_2, and a white light extraction region OP_w may be defined between the second data line DL_2 and the second power line PL_2.

The blue sub-pixel B-SP may be disposed between the second power line PL_2 and the third data line DL_3, and a blue light extraction area OP_b may be defined between the second power line PL_2 and the third data line DL_3. The green sub-pixel G-SP may be disposed between the fourth data line DL_4 and the reference line RL, and a green light extraction region OP_g may be defined between the fourth data line DL_4 and the reference line RL.

Here, boundary portions of the sub-pixels R-SP, W-SP, G-SP, and B-SP in which the data lines DL_1, DL_2, DL_3, and DL_4, the power lines PL_1, and PL_2, and the reference line RL are disposed may be defined as non-emission areas NEA.

A passivation layer 106 may be disposed on the gate insulating layer 105. A red color filter layer 160r may be disposed on the passivation layer of the red sub-pixel R-SP, and a green color filter layer 160g may be disposed on the passivation layer 106 of the green sub-pixel G-SP.

In addition, a blue color filter layer 160b may be disposed on the passivation layer 106 of the blue sub-pixel B-SP, and a color filter layer may be omitted on the passivation layer 106 in the white sub-pixel W-SP.

A first overcoat layer 210 may be disposed on the color filter layers 160r, 160g, 160b and the passivation layer 106 entirely over the substrate 120. The first overcoat layer 210 may have a plurality of concave portions 118 and a plurality of convex portions 117 alternately arranged to form microlenses ML.

Here, the first overcoat layer 210 positioned to correspond to each of the sub-pixels R-SP, W-SP, G-SP, and B-SP may be characterized in that it has inclined surfaces S_r, S_w, S_b, or S_g that are inclined toward opposite directions from both edge boundaries of the light extraction area OP_r, OP_w, OP_b, or OP_g. The both edges of the light extraction areas OP_r, OP_w, OP_b, or OP_g may mean edges having the longest length within the emission region (EA of FIG. 1) of each sub-pixel R-SP, W-SP, G-SP, or B-SP.

That is, the first overcoat layer 210 positioned to correspond to the red sub-pixel R-SP may include red inclined surfaces S_r inclined toward each other from the first power line PL_1 and the first data line DL_1, respectively. The first overcoat layer 210 positioned to correspond to the white sub-pixel W-SP may include white inclined surface S_w inclined toward each other from the second data line DL_2 and the second power line PL_2, respectively. The first overcoat layer 210 positioned to correspond to the blue sub-pixel B-SP may include blue inclined surfaces S_b inclined toward each other from the second power line PL_2 and the third data line DL_3, respectively. The first overcoat layer 210 positioned to correspond to the green sub-pixel G-SP may include green inclined surfaces S_g inclined toward each other from the fourth data line DL_4 and the reference line RL, respectively.

The second overcoat layer 220 positioned on the first overcoat layer 210 including the microlenses ML may expose the inclined surface S_r, S_w, S_b, and S_g of the first overcoat layer 210 and cover the microlens ML of the first overcoat layer 210 to have a flat surface.

The second overcoat layer 220 may further form inclined surfaces extending from the respective inclined surfaces S_r, S_w, S_b, and S_g of the first overcoat layer 210.

Accordingly, an anode 111 positioned on the second overcoat layer 220 may be positioned to cover the respective inclined surfaces S_r, S_W, S_b, and S_g of the first and second overcoat layers 210 and 220 and the flat surface of the second overcoat layer 220. Thus, the anode 111 may also include anode inclined surfaces 111_S corresponding to each inclined surface S_r, S_w, S_b, or S_g of the first and second overcoat layers 210 and 220. That is, each anode inclined surfaces 111_s overlaps a corresponding inclined surface S_r, S_w, S_b, or S_g of the first and second overcoat layers 210 and 220.

An organic light emitting layer 113 and a cathode 115 may be sequentially positioned on the anode 111. The organic light emitting layer 113 and the cathode 115 positioned on the anode 111 may also include inclined surfaces corresponding to the anode inclined surface 111_S. In particular, the cathode 115 may also include cathode inclined surfaces 115S_r, 115S_w, 115S_b, and 115S_g corresponding to the respective inclined surfaces S_r, S_w, S_b, and S_g of the first and second overcoat layers 210 and 220. That is, each cathode inclined surfaces 115S_r, 115S_w, 115S_b, and 115S_g overlaps a corresponding inclined surface S_r, S_w, S_b, or S_g of the first and second overcoat layers 210 and 220 and the anode inclined surfaces 111_s.

That is, the cathode inclined surfaces 115S_r, 115S_w, 115S_b, and 115S_g may be formed to correspond to the respective inclined surfaces S_r, S_w, S_b, and S_g of the first overcoat layer 210. Accordingly, in the organic light emitting diode display (100 of FIG. 2) according to the embodiment of the present disclosure, a light extraction efficiency is further improved, and the light extraction areas OP_r, OP_w, OP_b, and OP_g are formed more widely than the respective emission areas (EA of FIG. 2).

Accordingly, a luminance viewing angle is improved and an aperture ratio is improved, and thus a high luminance can also be realized.

That is, the organic light emitting layer 113, which directly generates lights L1 and L2 from the inside, emits the light L1 and L2 radially. The first light L1 as a part of the lights L1 and L2 emitted from the organic light emitting layer 113 passes through the anode 111 and is incident on the second overcoat layer 220, and the first light L1 passing through the second overcoat layer 220 has a propagation path changed toward the substrate 120 through the microlens ML of the first overcoat layer 210, so that the first light L1 passes through the first and second overcoat layers 210 and 220 and is condensed.

Then, the first light L1 passes through each of the color filter layers 160r, 160g, and 160b, and then passes through the substrate 120 to be output to the outside. Accordingly, in the organic light emitting diode display (100 of FIG. 2) according to the embodiment of the present disclosure, a light extraction efficiency is improved.

At this time, in the organic light emitting diode display (100 of FIG. 2) according to the embodiment of the present disclosure, since a second light L2 as a part of the radially emitted lights L1 and L2 has an angle greater than a total reflection critical angle to the substrate 120, it does not pass through the substrate 120 and is totally reflected at a boundary of the substrate 120, and thus it proceeds to the non-emission area NEA which is the boundary portion of each sub-pixel R-SP, W-SP, G-SP, or B-SP.

The second light L2 traveling to the non-emission area NEA may be trapped inside the organic light emitting diode display (100 of FIG. 2). However, in the organic light emitting diode display (100 of FIG. 2) according to an embodiment of the present disclosure, the second light L2 trapped in the non-emission area NEA is reflected by the cathode inclined surface 115S of the cathode 115 as a reflective electrode of each sub-pixel R-SP, W-SP, G-SP, or B-SP, so that it is extracted outside the substrate 120.

Accordingly, in the organic light emitting diode display (100 of FIG. 2) according to the embodiment of the present disclosure, a light extraction efficiency is further improved.

In particular, since the second light L2 reflected by the cathode inclined surfaces 115S_r, 115S_w, 115S_b, and 115S_g and extracted outside the substrate 120 is output from the non-emission areas NEA to the outside, the non-emission areas NEA also form the light extraction areas OP_r, OP_w, OP_b, and OP_g.

Accordingly, the organic light emitting diode display 100 according to the embodiment of the present disclosure can have the wide light extraction areas OP_r, OP_w, OP_b, and OP_g, thereby further improving an aperture ratio and realizing a higher luminance.

FIG. 13 is a graph of a luminance measured according to a viewing angle according to an embodiment of the present disclosure, and the horizontal axis indicates the viewing angle and the vertical axis indicates the luminance FIG. 14 is a graph showing a relative luminance ratio according to a viewing angle, and shows that the graph of FIG. 13 is normalized to convert a luminance of 600 nits to 100%.

Case A represents a general organic light emitting diode display, and case G represents an organic light emitting diode display according to the embodiment of the present disclosure, in which the first overcoat layer 210 positioned corresponding to each sub-pixel R-SP, W-SP, G-SP, or B-SP includes the inclined surfaces S_r, S_w, S_b, or S_g inclined toward opposite directions from both edge boundaries of the light extraction area OP_r, OP_w, OP_b, or OP_g.

Referring to FIGS. 13 and 14, it is seen that the luminance of case G is higher in both a central luminance and a side luminance than case A.

In particular, referring to FIG. 14, it is seen that case A has a luminance ratio of 89% at a viewing angle of 30 degrees, whereas case G has a luminance ratio of 100% even at a viewing angle of 30 degrees.

Accordingly, it is seen that case G has both the central luminance and the luminance viewing angle better than those of case A.

That is, in the organic light emitting diode display (100 of FIG. 2) according to the embodiment of the present invention, the first overcoat layer 210 positioned corresponding to each sub-pixel R-SP, W-SP, G-SP, or B-SP includes the inclined surfaces S_r, S_w, S_b, or S_g inclined toward opposite directions from both edge boundaries of the light extraction area OP_r, OP_w, OP_b, or OP_g, so that a light extraction efficiency is improved to realize a high luminance, and a luminance viewing angle is also improved to further improve an aperture ratio.

At this time, as shown in FIG. 15, regarding an angle between a bottom surface of the first overcoat layer 210 and each of the inclined surfaces S_r, S_w, S_b, or S_g, it is preferable that the angle of the blue inclined surface S_b is formed to be the largest, and the angles of the green inclined surface S_g, the red inclined surface S_r, and the white inclined surface S_w are formed to be smaller in the order.

This is to form angles of the cathode inclined surfaces 115S_r, 115S_w, 115S_b, and 115S_g to be lower as the luminance viewing angles decrease because the cathode inclined surfaces 115S_r, 115S_w, 115S_b, and 115S_g are formed to correspond to the inclined surfaces S_r, S_w, S_b, and S_g of the first overcoat layer 210.

In this regard, by forming the angles of the cathode inclined surfaces 115S_r, 115S_w, 115S_b, and 115S_g to be low, a light having a low luminance viewing angle can be directed more toward the light extraction areas OP_r, OP_w, OP_b, and OP_g.

FIG. 16 is a graph measuring a luminance viewing angle for each color, and the horizontal axis indicates a viewing angle and the vertical axis indicates a relative luminance ratio (a.u. (arbitrary unit)) to a front.

Referring to FIG. 16, it is seen that as a viewing angle increases, a luminance of the blue light is lower, and luminances of the green light, the red light, and the white light are lowered in the order.

Accordingly, in one embodiment the angle between the blue inclined surface S_b of the first overcoat layer 210 of the blue sub-pixel B-SP and the bottom surface is formed to be the largest, and the angles of the green inclined surface S_g, the red inclined surface S_r, and the white inclined surface S_w are formed to be lower in the order.

Accordingly, regarding the cathode inclined surfaces 115S_r, 115S_w, 115S_b, and 115S_g, the blue cathode inclined surface 115S_b may form the largest angle with the bottom surface, the green cathode inclined surface 115S_g form the next largest angle with the bottom surface, and the red cathode inclined surface 115S_r and the white cathode inclined surface 115S_w form angles with the bottom surface to be lowered in the order. Thus, at least two of the inclined surfaces of different color sub-pixels have different angles.

Accordingly, a blue light having a low luminance viewing angle can be directed more to the blue light extraction area OP_b, and a green light, a red light, and a white light can be sequentially directed to the light extraction areas OP_g, OP_r, and OP_w, respectively, so that lights of uniform luminance can be output from the respective sub-pixels R-SP, W-SP, G-SP, and B-SP.

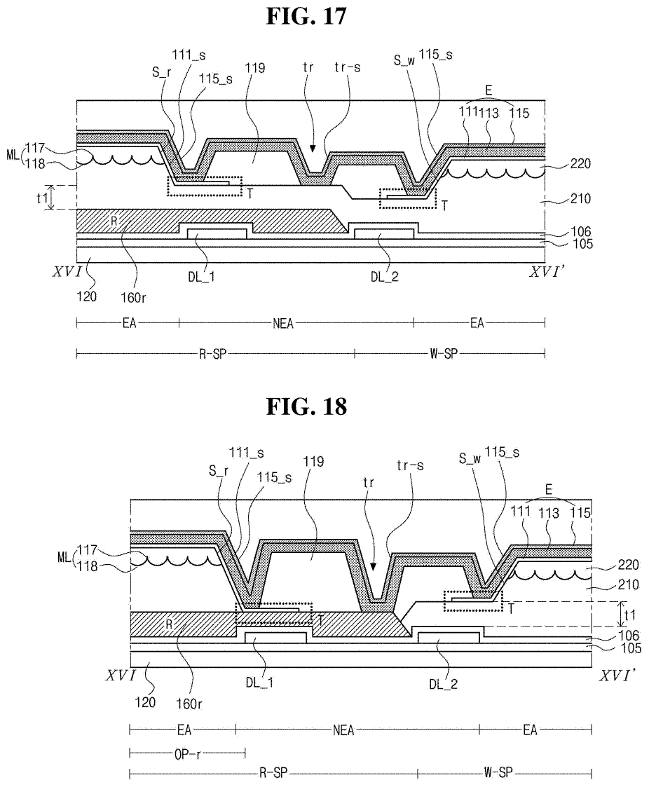

FIGS. 17 and 18 are cross-sectional views illustrating non-emission areas of sub-pixels, and are cross-sectional views taken along a line XVI-XVI′ of FIG. 1 according to one embodiment.

As shown in FIG. 17, the red color filter layer 160r positioned to correspond to the red sub-pixel R-SP may be formed to extend from the emission area EA of the red sub-pixel R-SP to a portion of the non-emission area NEA.

That is, the red color filter layer 160r may be formed to cover the first data line DL_1 and extend to one end of the second data line DL_2 facing the first data line DL_1.

At this time, the first overcoat layer 210 positioned on the red color filter layer 160r may have a first thickness t1 below the red inclined surface S_r and extend to the non-emission area NEA, and the first overcoat layer 210 of the white sub-pixel W-SP may also have a first thickness t1 below the white inclined surface S_w and extend to the non-emission area NEA.

That is, the first overcoat layer 210 may have a first thickness t1 corresponding to the non-emission area NEA and may have a structure connected entirely over the substrate 120. In other words, a portion of the first overcoat layer 210 corresponding to an end of an inclined surface of the first overcoat layer 210 at the non-emission area NEA has a thickness that is less than a thickness of a portion of the first overcoat layer 210 having the microlens ML. In this case, the first thickness t1 of the first overcoat layer 210 may correspond to a thickness from the concave portion 118 of the microlens ML to the bottom surface of the first overcoat layer 210.

Meanwhile, the portion of the first overcoat layer 210 extending to the non-emission area NEA between the red sub-pixel R-SP and the white sub-pixel W-SP may include a flat portion T along a surface of the red color filter layer 160r or a surface of the second data line DL_2 below the first overcoat layer 210. The anode 111 of the red sub-pixel R-SP may extend to a part of the flat portion T of the first overcoat layer 210, and the anode 111 of the white sub-pixel W-SP may also extend to a part of the flat portion T of the first overcoat layer 210.

Accordingly, a process margin can be secured in forming the anode 111.

In this case, the bank 119 positioned to cover the non-emission area NEA between the red sub-pixel R-SP and the white sub-pixel W-SP may further include a trench tr, and the trench tr may expose a portion of the first overcoat layer 210 positioned there below.

When the trench tr is formed in the bank 119, the cathode 115 may be also formed along the surface of the trench tr. The cathode 115 formed along the surface of the trench tr may also include an inclined surface tr-s in the non-emission area NEA.

Accordingly, by making light, which is incident to the non-emission area NEA among light emitted from the organic light emitting layer 113, be reflected by the inclined surface tr-s of the cathode 115 of the trench tr, a light extraction efficiency is improved. In addition, it is also possible to prevent or at least reduce light emitted from each of the sub-pixels R-SP and W-SP from being incident on the adjacent sub-pixel R-SP or W-SP, partially mixed with colors, and then emitted.

That is, as a part of the red light emitted from the red sub-pixel R-SP is directed toward the neighboring white sub-pixel W-SP, the white light is partially mixed with the part of the red light and then emitted, and in this case, a color reproducibility is lowered. However, in the organic light emitting diode display (100 of FIG. 2) according to the embodiment of the present disclosure, the trench tr is formed in the bank 119 located in the non-emission area NEA corresponding to the boundary of the sub-pixels R-SP and W-SP, it is possible to prevent color mixing from occurring in the adjacent sub-pixels R-SP and W-SP.

Accordingly, a color reproducibility of light is improved.

In addition, as shown in FIG. 18, the red inclined surface S_r of the first overcoat layer 210 of the red sub-pixel R-SP may be formed to extend to the non-emission area NEA at the same angle formed with the bottom surface of the first overcoat layer 210.

Accordingly, the light extraction area OP_r increases, and thus an amount of a light reflected through the inclined surface S_r can be further increased.

At this time, in the white sub-pixel W-SP where a color filter layer is not provided, the first overcoat layer 210 may extend from the white inclined surface S_w to the non-emission area NEA at the first thickness t1 to form the non-emission area NEA to be flat.

As described above, in the organic light emitting diode display (100 of FIG. 2) according to the embodiment of the present disclosure, the first and second overcoat layers 210 and 220 having different refractive indices are stacked on each other, the first overcoat layer 210 includes the microlenses ML, and the second overcoat layer 220 covers the microlenses ML to be planarized, thereby improving a light extraction efficiency and preventing an occurrence of a rainbow mura.

In addition, by preventing an occurrence of a high reflectance, it is possible to prevent or at least reduce a deterioration of a visibility of a black color, so that a contrast ratio is improved.

In addition, by making the first and second overcoat layers 210 and 220 have a refractive index difference of 0.2, a light extraction efficiency can be further improved, and each of the sub-pixels R-SP, W-SP, G-SP, and B-SP can have a uniform emission characteristic, thereby improving an efficiency of the organic light emitting layer 113 and also increasing a lifespan of the organic light emitting layer 113.

In particular, the radius (r) and aspect ratio (A/R) of the concave portion 118 of the microlens ML for each of the sub-pixels R-SP, W-SP, G-SP, and B-SP are designed to suit each color characteristic. Accordingly, it is possible to have the maximum luminance efficiency increase rate for each of the sub-pixels R-SP, W-SP, G-SP, and B-SP, thereby further improving the light extraction efficiency.

In addition, in the organic light emitting display device according to an embodiment of the present disclosure, by forming the first overcoat layer to include the inclined surface corresponding to the boundary of each sub-pixel, a light extraction efficiency can be further improved, and the light extraction area OP can be formed to be wider than the emission area EA, for example, in a direction perpendicular to a direction in which the data line extends, thus a luminance viewing angle can also be improved. Accordingly, an aperture ratio can be improved, and thus a high luminance can also be realized.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic light emitting diode display, comprising:
a substrate including a plurality of sub-pixels, the plurality of sub-pixels comprising a red sub-pixel, a green sub-pixel, and a blue sub-pixel that each have a non-emission area and an emission area;
a plurality of thin film transistors, each thin film transistor in the non-emission area of a corresponding sub-pixel from the plurality of sub-pixels;
a first overcoat layer covering the plurality of thin film transistors, the first overcoat layer having a first refractive index and a plurality of microlenses at a surface of the first overcoat layer;
a second overcoat layer on the first overcoat layer, the second overcoat layer having a second refractive index that is greater than the first refractive index of the first overcoat layer and having a substantially flat surface; and
a plurality of light emitting diodes on the second overcoat layer, each light emitting diode in the emission area of a corresponding sub-pixel from the plurality of pixels,
wherein a radius and an aspect ratio of a concave portion of a microlens of the red sub-pixel and a radius and an aspect ratio of a concave portion of a microlens of the green sub-pixel are different from a radius and an aspect ratio of a concave portion of a microlens of the blue sub-pixel.

2. The organic light emitting diode display of claim 1, wherein the concave portion of the microlens of the red sub-pixel and the concave portion of the microlens of the green sub-pixel has a first radius and a first aspect ratio, and the concave portion of the microlens of the blue sub-pixel has a second radius that is different from the first radius and a second aspect ratio that is different from the first aspect ratio.

3. The organic light emitting diode display of claim 2, wherein the first radius is 1.75 μm and the first aspect ratio is 1, and the second radius of 2.0 μm and the second aspect ratio of 1.25.

4. The organic light emitting diode display of claim 2, wherein the plurality of sub-pixels further comprise a white sub-pixel on the substrate,
wherein a concave portion of a microlens of the white sub-pixel has a same radius and a same aspect ratio as the concave portion of the microlens of the red sub-pixel and the concave portion of the green sub-pixel.

5. The organic light emitting diode display of claim 1, wherein the first refractive index is in a range of 1.43 to 1.57, and the second refractive index is in a range of 1.57 to 1.8.

6. The organic light emitting diode display of claim 5, wherein a difference between the first refractive index and the second refractive index is 0.2.

7. The organic light emitting diode display of claim 1, wherein a red color filter layer is between the substrate and a portion of the first overcoat layer on the red sub-pixel, a green color filter layer is between the substrate and a portion of the first overcoat layer on the green sub-pixel, and a blue color filter layer is between the substrate and a portion of the first overcoat layer on the blue sub-pixel.

8. The organic light emitting diode display of claim 1, wherein the first overcoat layer includes a plurality of inclined surfaces toward opposite directions from boundaries between the red sub-pixel, the green sub-pixel, and the blue sub-pixel.

9. The organic light emitting diode display of claim 1, wherein the first overcoat layer includes inclined surfaces toward opposite directions from both edge boundaries of a light extraction area having a longest length in an emission area of each of the red sub-pixel, the green sub-pixel, and the blue sub-pixel.

10. The organic light emitting diode display of claim 1, wherein a portion of the first overcoat layer corresponding to the red sub-pixel includes a first inclined surface, and a portion of the first overcoat layer corresponding to the green sub-pixel includes a second inclined surface, and a portion of the first overcoat layer corresponding to the blue sub-pixel includes a third inclined surface, and
wherein the first inclined surface, the second inclined surface, and the third inclined surface have different angles with a surface of the substrate.

11. The organic light emitting diode display of claim 10, wherein a first angle between the third inclined surface and the surface of the substrate is greater than a second angle between the second inclined surface and the surface of the substrate.

12. The organic light emitting diode display of claim 10, wherein a first angle between the third inclined surface and the surface of the substrate is greater than a second angle between the second inclined surface and the surface of the substrate, and is greater than a third angle between the first inclined surface and the surface of the substrate, and
wherein the second angle is greater than the third angle.

13. The organic light emitting diode display of claim 10, wherein the plurality of sub-pixels further comprise a white sub-pixel on the substrate and a portion of the first overcoat layer corresponding to the white sub-pixel has a fourth inclined surface, and
wherein angles formed by the third inclined surface, the second inclined surface, the first inclined surface, and the fourth inclined surface, respectively, with the surface of the substrate increase in an order of the third inclined surface, the second inclined surface, the first inclined surface, and the fourth inclined surface.

14. The organic light emitting diode display of claim 8, wherein the second overcoat layer includes an inclined surface along an inclined surface from the plurality of inclined surfaces of the first overcoat layer, and
wherein an anode of a light emitting diode from the plurality of light emitting diodes covers the substantially flat surface of the second overcoat layer and includes an inclined surface that overlaps the inclined surface of the first overcoat layer and the inclined surface of the second overcoat layer.

15. The organic light emitting diode display of claim 14, wherein the light emitting diode further includes a cathode on the anode with an organic light emitting layer between the anode and the cathode, the cathode including an inclined surface that overlaps the inclined surface of the anode.

16. The organic light emitting diode display of claim 1, wherein a light emitting diode from the plurality of light emitting diodes includes a cathode with inclined surfaces toward opposite directions from boundaries between the red pixel, the green sub-pixel, and blue sub-pixel.

17. The organic light emitting diode display of claim 16, wherein a cathode corresponding to the red sub-pixel includes a first inclined surface that overlaps a first inclined surface of the first overcoat layer, a cathode corresponding to the green sub-pixel includes a second inclined surface that overlaps a second inclined surface of the first overcoat layer, and a cathode corresponding to the blue sub-pixel includes a third inclined surface that overlaps a third inclined surface of the first overcoat layer, and
wherein the first inclined surface of the cathode corresponding to the red sub-pixel, the second inclined surface of the cathode corresponding to the green sub-pixel, and the third inclined surface of the cathode corresponding to the blue sub-pixel have different angles with a surface of the substrate.

18. The organic light emitting diode display of claim 17, wherein a first angle between the third inclined surface of the cathode corresponding to the blue sub-pixel and the surface of the substrate is greater than a second angle between the second inclined surface of the cathode corresponding to the green sub-pixel and the surface of the substrate and is greater than a third angle between the first inclined surface of the cathode corresponding to the red sub-pixel and the surface of the substrate, and
wherein the second angle is greater than the third angle.

19. The organic light emitting diode display of claim 17, wherein the plurality of sub-pixels further comprise a white sub-pixel and a cathode corresponding to the white sub-pixel includes a fourth inclined surface that overlaps a fourth inclined surface of the first overcoat layer, and
wherein angles formed by the third inclined surface of the cathode corresponding to the blue sub-pixel, the second inclined surface of the cathode corresponding to the blue sub-pixel, the first inclined surface of the cathode corresponding to the red sub-pixel, and the fourth inclined surface of the cathode corresponding to the white sub-pixel, respectively, with the surface of the substrate increase in an order of the third inclined surface of the cathode corresponding to the blue sub-pixel, the second inclined surface of the cathode corresponding to the green sub-pixel, the first inclined surface of the cathode corresponding to the red sub-pixel, and the fourth inclined surface of the cathode corresponding to the white sub-pixel.

20. The organic light emitting diode display of claim 8, wherein a portion of the first overcoat layer corresponding to an end of an inclined surface from the plurality of inclined surfaces at the non-emission area has a thickness that is less than a thickness of a portion of the first overcoat layer having a microlens from the plurality of microlenses.

21. The organic light emitting diode display of claim 20, wherein a portion of the first overcoat layer extending into the non-emission area includes a flat portion, and an anode of a light emitting diode from the plurality of light emitting diodes extends onto the flat portion.

22. The organic light emitting diode display of claim 8, wherein an inclined surface from the plurality of inclined surfaces of the first overcoat layer extends to the non-emission area.

23. The organic light emitting diode display of claim 1, further comprising:
a bank along an edge of the emission area; and
a trench in the bank.

24. The organic light emitting diode display of claim 23, wherein a light extraction area from which light emitted from a light emitting diode from the plurality of light emitting diodes is output is wider than the emission area.

25. A display device comprising:
a substrate including a plurality of sub-pixels each having an emission area and a non-emission area, the plurality of sub-pixels including a first sub-pixel configured to emit light of a first color, a second sub-pixel configured to emit light of a second color, and a third sub-pixel configured to emit light of a third color;
a plurality of thin film transistors, each thin film transistor in the non-emission area of a corresponding sub-pixel from the plurality of sub-pixels;
a first overcoat layer on the plurality of thin film transistors and including a plurality of microlenses at a surface of the first overcoat layer, the plurality of microlenses including a first microlens in the emission area of the first pixel, a second microlens in the emission area of the second pixel, and a third microlens in the emission area of the third pixel;
a second overcoat layer on the first overcoat layer; and
a plurality of light emitting diodes on the second overcoat layer, each light emitting diode in the emission area of a corresponding sub-pixel from the plurality of pixels,
wherein a radius and an aspect ratio of a concave portion of the first microlens is a same as a radius and an aspect ratio of a concave portion of the second microlens, but the radius and the aspect of the concave portion of the first microlens and the radius and the aspect of a concave portion of the second microlens are different from a radius and an aspect ratio of a concave portion of the third microlens.

26. The display device of claim 25, wherein the first color of light emitted by the first sub-pixel is red light, the second color of light emitted by the second sub-pixel is green light, and the third color of light emitted by the third sub-pixel is blue light.

27. The display device of claim 26, wherein the radius of the concave portion of the first microlens and the radius of the concave portion of the second microlens is 1.75 μm, and the aspect ratio of the concave portion of the first microlens and the aspect ratio of the concave portion of the second microlens is 1, and
wherein the radius of the concave portion of the third microlens is 2.0 μm and the aspect ratio of the concave portion of the third microlens 1.25.

28. The display device of claim 25, wherein a refractive index of the second overcoat layer is greater than a refractive index of the first overcoat layer such that a difference between the refractive index of the second overcoat layer and the refractive index of the first overcoat layer is 0.2.

29. The display device of claim 25, wherein a portion of the first overcoat layer in the emission area of one of the plurality of sub-pixels includes a plurality of inclined surfaces at a boundary of the one of the plurality of sub-pixels.
